(19) United States
(12) Patent Application Publication
(10) Pub. No.: US 2011/0299008 A1
(43) Pub. Date: Dec. 8, 2011

(54) LCD Backlighting with LED Phosphors

(75) Inventors: Holger Winkler, Darmstadt (DE); Thomas Juestel, Witten (DE)

(73) Assignee: MERCK PATENT GESELLSCHAFT, Darmstadt (DE)

(21) Appl. No.: 12/674,373

(22) PCT Filed: Jul. 23, 2008
(86) PCT No.: PCT/EP2008/006007

§ 371 Date: Feb. 19, 2010

(30) Foreign Application Priority Data
Aug. 20, 2007 (DE) 10 2007 039 260.7

(51) Int. Cl. G02F 1/13357; F21V 9/16; H05K 13/00; G02F 1/1335

(52) U.S. Cl. 349/61; 362/97.2; 362/84; 29/592.1

(57) ABSTRACT

The invention relates to a liquid-crystal display fitted with a backlighting system having a white light source which comprises a semiconductor diode and a phosphor layer comprising a combination of at least two phosphors, where at least one phosphor emits red light and at least one phosphor emits green light, and to a process for the production thereof.

The invention relates to a liquid-crystal display with a backlighting system having a white light source which comprises a semiconductor diode and a phosphor layer comprising a combination of at least two phosphors, where at least one phosphor emits red light and at least one phosphor emits green light. The invention furthermore relates to a backlighting system and to the process for the production thereof.

Liquid-crystal displays (LCDs) are passive display systems, i.e. they do not themselves luminesce. These displays are based on the principle that light passes through the layer of liquid crystals or not. This means that an external light source is required in order to produce an image. In reflective liquid-crystal displays, the ambient light is utilised as the external light source, meaning that in principle backlighting is unnecessary. In transmissive liquid-crystal displays, light is generated in a backlighting system. In the meantime, transflective liquid-crystal displays (transmissive and reflective at the same time), in which a transflector is generally located behind the polariser facing away from the observer, are also playing a greater role. Each pixel here is divided into a reflective sub-pixel and a transmissive sub-pixel, whose associated liquid-crystal layer thicknesses are approximately in the ratio 1:2. The reflective part works with ambient light and has a reflective substrate layer, for example made of aluminium. The transmissive part behaves, for example, like a TN (=twisted nematic) cell and is able to achieve the requisite contrast by means of backlighting which can be switched on, especially in the case of poor external light conditions. The latter are used today, for example, in PDAs, games (Game Boys), view-finders for digital cameras or in (cheap) notebooks, since they are, inter alia, power-saving.

In liquid-crystal displays, primary colours of the pixels can be generated by filtering white light from the backlighting into the primary colours blue, green and red, for example, with the aid of coloured filters. The colour space that the display is able to generate, which is important for the display of colours, is limited by the purity of the blue, green and red primary colour. Transferred to a CIE xy colour diagram, the red, green and blue primary colours of the display form a triangle which indicates the colour space that can be displayed by the display. Colours outside this colour space cannot be displayed by the display.

In liquid-crystal displays, the colour space is determined by a number of factors:

The first is the light source for the backlighting and the construction of the LCD panel itself: each pixel of the screen consists of red, green and blue regions. The colours of these regions are generated by transmission of the white light from the backlighting through a coloured-filter field. The coloured filters are one of the determining factors for the colour space of the display. Broadband-emitting light sources, such as CCFLs (cold cathode fluorescent lamps=Hg low-pressure cold cathode discharge lamps) or xenon discharge lamps, which emit a broad colour spectrum with components of undesired colours, such as, for example, orange, yellow and cyan, are usually used for the backlighting for LCDs. In order to maximise the colour space that can be displayed by the screen, only red, green and blue in the highest possible purity are required. The primary colours must be saturated, since the white light from the primary light source is re-split into the primary colours by the coloured filters.

In order to enlarge the colour space, it is in this case necessary to convert the light from the backlighting into a spectrum comprising narrower bands of blue, green and red components through the use of additional coloured filters. Besides the technical complexity of additional colour filtration of this type, the luminous flux is greatly reduced here, causing a reduction in the brightness of the screen.

In order to circumvent these disadvantages of broadband backlighting, the CCFLs which result in a restricted colour space and reduced screen brightness due to the additional complex coloured filters necessary have therefore recently been replaced by LED arrays. These arrays consist of blue, green and red LEDs, which emit a much narrower-band spectrum compared with CCFLs. For this reason, the colour space that can be displayed by the display is larger and the achievable brightness is greater since only simple coloured filters are required. Further advantages arising therefrom are the higher energy efficiency of the display, since the backlighting transmittance in LEDs (70%) is significantly greater than in CCFLs (5%). Furthermore, LED backlighting has a significantly longer lifetime than CCFLs (100,000 operating hours in the case of LEDs compared with 5000 operating hours in the case of CCFLs), and mercury, which is unavoidable in CCFLs, is not employed in LEDs.

The disadvantage in the case of the use of blue, green and red LEDs for backlighting is, however, that the semiconductor chips of the LEDs are different: InGaN is employed for blue light, InGaN is likewise employed for green light (but with a higher In content), and InGaAIP is employed as the material basis for red light. These three materials exhibit different efficiencies for the emission of light and have different degradation behaviour. As a consequence, it is necessary to employ a complex active control system, which keeps the colour point of the white light composed of the blue, green and red LEDs constant via control circuits which engage in the LED addressing.

This complex active control system for each individual LED of the backlighting (up to several thousand LEDs) results in such high costs that LCD TV screens fitted therewith are 4-10 times more expensive than screens fitted with CCFLs.

The high price prevents market penetration of LED backlighting, which is qualitatively far better.

WO 02/095791 describes a liquid-crystal screen fitted with a gas-discharge lamp (cold cathode lamp or Xe discharge lamp) as white light source, which comprises a phosphor layer comprising a combination of phosphors which emit red, green and blue light.

The object of the present invention was to provide a backlighting system which has the same high quality (with respect to displayable colour space and brightness) as R, G, B LED backlighting, but does so at significantly lower cost.

Surprisingly, it has now been found that, on use of certain LEDs, the use of the complex active control system for each individual LED can be omitted and these LEDs can be employed in conventional backlighting systems. These LEDs according to the invention allow less expensive backlighting, which is associated with lower costs, calculated over the lifetime of the screen, than conventional CCFL backlighting.

The present invention thus relates to a liquid-crystal display fitted with at least one backlighting system having at least one white light source, which comprises at least one semiconductor diode, preferably blue-emitting, and at least one phosphor layer comprising a combination of at least two phosphors, where at least one phosphor emits red light and at least one phosphor emits green light.

A liquid-crystal display usually has a liquid-crystal unit and a backlighting system. The liquid-crystal unit typically comprises a first polariser and a second polariser and a liquid-crystal cell which has two transparent layers, each of which carries a matrix of light-transparent electrodes. A liquid-crystal material is arranged between the two substrates. The liquid-crystal material comprises, for example, TN (twisted nematic) liquid crystals, STN (supertwisted nematic) liquid crystals, DSTN (double supertwisted nematic) liquid crystals, FSTN (foil supertwisted nematic) liquid crystals, VAN (vertically aligned) liquid crystals or OCB (optically compensated bend) liquid crystals. The liquid-crystal cell is surrounded in a sandwich-like manner by the two polarisers, where the second polariser can be seen by the observer.

Also very highly suitable for monitor applications is IPS (in-plane switching) technology. In contrast to the TN display, the electrodes in whose electric field the liquid-crystal molecules are switched are only located on one side of the liquid-crystal layer in the IPS cell. The resultant electric field is inhomogeneous and, to a first approximation, aligned parallel to the substrate surface. The molecules are correspondingly switched in the substrate plane (in plane), which results in a significantly lower viewing-angle dependence of the transmitted intensity compared with the TN display. Another, less well-known technique for good optical properties over a broad viewing angle is FFS technology and a further development thereof, AFFS (advanced fringe field switching) technology. It has a similar functional principle to IPS technology.

The present invention furthermore relates to a backlighting system having a white light source which comprises a semiconductor diode, preferably blue-emitting, and a phosphor layer comprising a combination of at least two phosphors which emit red and green light.

The backlighting system according to the invention can be, for example, a “direct-lit” backlighting system (see FIG. 1) or a “side-lit” backlighting system (see FIG. 2), which has an optical waveguide and an outcoupling structure. The backlighting system has a white light source, which is usually located in a housing, which preferably has a reflector on the inside. The backlighting system may furthermore have at least one diffuser plate.

In order to produce and display coloured images, the liquid-crystal unit is provided with a coloured filter. The coloured filter contains pixels in a mosaic-like pattern which transmit either red, green or blue light. The coloured filter is preferably arranged between the first polariser and the liquid-crystal cell.

The white (primary) light source comprises a blue-emitting indium aluminium gallium nitride semiconductor diode, in particular of the formula InᵢGaⱼAlₖN, where 0≦i, 0≦j, 0≦k, and l+j+k=1. It is preferably an InGaN semiconductor diode, which, in combination with corresponding conversion phosphors, preferably emits white or virtually white light. This InGaN semiconductor diode has an emission maximum between 430 nm and 480 nm and has very high efficiency and a long lifetime (>150,000 hours), with only very slight degradation of the efficiency.

In a further embodiment, the white light source can also be a luminescent compound based on ZnO, TCO (transparent conducting oxide), ZnSe or SiC.

In principle, a multiplicity of designs, which are selected in accordance with the application, are possible for a blue-emitting semiconductor diode which generates white light in combination with a phosphor layer.

In accordance with the invention, the white light source has a phosphor layer comprising a combination of red- and green-emitting phosphors.

The present invention furthermore relates to a process for the production of a liquid-crystal display fitted with a backlighting system having a white light source, comprising the following steps:
Production of at least one LED which is built up from a blue-emitting InGaAlN semiconductor, in particular of the formula InᵢGaⱼAlₖN, where 0≦i, 0≦j, 0≦k, and l+j+k=1, and a phosphor layer which comprises a combination of a red-emitting phosphor and a green-emitting phosphor.
Installation of one or more LEDs in a housing to give a backlighting system containing diffusers and reflectors.
The backlighting system is combined with a corresponding liquid-crystal unit, containing a front plate with a coloured-filter system, to give the liquid-crystal display.

The green-emitting phosphors, which are excited by the blue-emitting primary light source, have emission maxima between 520 and 550 nm. Preference is given in accordance with the invention to all cerium(III)- or europium(II)-activated phosphors, which are selected from the group of the thiogallates, silicates, oxonitridosilicates, aluminates, nitrides or garnets. Mention may be made here by way of example of these phosphors of (Y,Lu)₃(Al,Ga)₅O₁₂:Ce; SrSi₂N₂O₂:Eu; SrGa₂S₄:Eu; (Sr,Ba)₂SiO₄:Eu and SrAl₂O₄:Eu.

These are prepared by conventional methods via solid-state synthesis or also by wet-chemical methods (see William M. Yen, Marvin J. Weber, Inorganic Phosphors, Compositions, Preparation and optical properties, CRC Press, New York, 2004).

The red-emitting phosphors, which are preferably line emitters, are excited either by the blue-emitting primary light source or by the green-emitting phosphor. The red-emitting phosphors are preferably europium(III)- or chromium(III)-activated line emitters. In accordance with the invention, they have either an emission maximum between 590 and 620 nm (in the case of Eu(III)-activated phosphors) or a maximum between 680 and 700 nm (in the case of Cr(III)-activated phosphors). The phosphor layer particularly preferably comprises, as red-emitting phosphor, a europium- or chromium-activated line emitter selected from the group Al₂O₃:Cr, Na_{0.5}Gd_{0.3}Eu_{0.2}WO₄, Na_{0.5}Y_{0.4}Eu_{0.1}MoO₄, Na_{0.5}La_{0.3}Eu_{0.2}WO₄, Na_{0.5}La_{0.3}Eu_{0.2}MoO₄, Na_{0.5}La_{0.3}Eu_{0.2}(WO₄)_{0.5}(MoO₄)_{0.5}, La_{1.2}Eu_{0.8}MoO₄, La_{1.2}Eu_{0.8}WO₄, (Gd_{0.6}Eu_{0.4})₂(WO₄)_{1.5}PO₄.

Al₂O₃:Cr (ruby) is stimulated efficiently in the yellowish-green region of the spectrum to emit a dark-red line at 693 nm. Eu(III)-activated phosphors can be employed if use is made of a matrix which (partially) allows the forbidden internal f-f absorption transitions of europium.

The red line emitter Al₂O₃:Cr, which is preferred in accordance with the invention, can be prepared by wet-chemical methods (see DE 102006054328.9 and DE 102007001903.5). These rubies can consequently be produced very inexpensively and are suitable as conversion phosphor for pcLEDs for the generation of warm white light with high efficiency and superior colour reproduction owing to dark-red emission. These phosphors can be prepared in a wet-chemical process, giving Al₂O₃ particles doped with 0.01 to 10% by weight of Cr³⁺ or Cr₂O₃, which have an adjustable size and uniform morphology.

The starting materials for the preparation of the phosphor consist of the base material (for example salt solutions of aluminium) and at least one Cr(III)-containing dopant. Suitable starting materials are inorganic and/or organic substances, such as nitrates, carbonates, hydrogencarbonates, hydrogenphosphates, phosphates, carboxylates, alcoholates, acetates, oxalates, halides, sulfates, organometallic compounds, hydroxides and/or oxides of the metals, semimetals, transition metals and/or rare earths, which are dissolved and/or suspended in inorganic and/or organic liquids. Preference is given to the use of mixed nitrate solutions, chloride or hydroxide solutions which contain the corresponding elements in the requisite stoichiometric ratio.

A further advantage of the red-emitting phosphor according to the invention consists in that the luminance of the phosphor increases with increasing temperature. This is surprising since the luminance of phosphors usually decreases with increasing temperature. This advantageous property according to the invention is of particular importance on use of phosphors in high-power LEDs (>1 watt energy consumption), since these can come to operating temperatures of above 150° C.

The wet-chemical preparation generally has the advantage that the resultant materials have greater uniformity with respect to the stoichiometric composition, the particle size and the morphology of the particles from which the red line emitter according to the invention is prepared. The wet-chemical preparation of the phosphor is preferably carried out by the precipitation and/or sol-gel process.

The preparation of the line emitter according to the invention is carried out by conventional processes from the corresponding metal and/or rare-earth salts, preferably from an aluminium sulfate, potassium sulfate, sodium sulfate and chrome alum solution. The preparation process is described in detail in EP 763573.

Phosphors or precursors thereof are applied here to the ruby particles under the process conditions known to the person skilled in the art. After separation from the suspension, the material is dried and subjected to a calcination process, which can be carried out in a number of steps and (partially) under reducing conditions at temperatures up to 1700° C. After a plurality of purification steps, the phosphor is calcined for a number of hours at temperatures between 600 and 1800° C., preferably between 800 and 1700° C. The phosphor precursor is converted here into the actual phosphor.

It is preferred to carry out the calcination at least partially under reducing conditions (for example using carbon monoxide, forming gas, pure or dilute hydrogen or at least vacuum or oxygen-deficiency atmosphere).

Furthermore, the red line emitter according to the invention can also be prepared by means of single-crystal synthesis methods (for example by the Verneuil process, see Kontakte (Merck) 1991, No. 2, 17-32, or Ullmann (4.) 15, 146, source: CD Römpp Chemie Lexikon [CD Römpp's Lexicon of Chemistry]—Version 1.0, Stuttgart/New York: Georg Thieme Verlag 1995). The methods mentioned are in use under names such as Kyropoulus, Bridgman-Stockbarger, Czochralski, Verneuil process and as hydrothermal synthesis. A distinction is also made between crucible-free zone melting and crucible drawing (source: CD Römpp Chemie Lexikon [CD Römpp's Lexicon of Chemistry]—Version 1.0, Stuttgart/New York: Georg Thieme Verlag 1995).

The red-emitting line emitters Na_{0.5}Gd_{0.3}Eu_{0.2}WO₄, Na_{0.5}Y_{0.4}Eu_{0.1}MoO₄, Na_{0.5}La_{0.3}Eu_{0.2}WO₄, Na_{0.5}La_{0.3}Eu_{0.2}MoO₄, Na_{0.5}La_{0.3}Eu_{0.2}(WO₄)_{0.5}(MoO₄)_{0.5}, La_{1.2}Eu_{0.8}MoO₄, La_{1.2}Eu_{0.8}WO₄, (Gd_{0.6}Eu_{0.4})₂(WO₄)_{1.5}PO₄ are preferably prepared by wet-chemical methods and subsequently thermally treated (see DE 102006027026.6). Starting materials which can be employed for the preparation are nitrates, halides and/or phosphates of the corresponding metals, semimetals, transition metals and/or rare earths. In accordance with the invention, the dissolved or suspended starting materials are heated with a surface-active agent, preferably a glycol, for a number of hours, and the resultant intermediate is isolated at room temperature using an organic precipitation reagent, preferably acetone. After purification and drying of the intermediate, the latter is subjected to thermal treatment at temperatures between 600 and 1200° C. for a number of hours, giving the red line emitter phosphor as end product.

Both the red-emitting and green-emitting conversion phosphors, which represent the phosphor layer, are chemically stable to decomposition during operation of the LED, i.e. they exhibit no tendency to hydrolysis and no reaction with materials from their environment.

The following examples are intended to illustrate the present invention. However, they should in no way be regarded as limiting. All compounds or components which can be used in the compositions are either known and commercially available or can be synthesised by known methods.

### EXAMPLES

### Example 1

### Production of Red-Emitting Phosphor Particles of the Composition Al_{1.991}O₃:Cr_{0.009}

223.8 g of aluminium sulfate 18-hydrate, 114.5 g of sodium sulfate, 93.7 g of potassium sulfate and 2.59 g of KCr(SO₄)₂×12H₂O (chromium alum) are dissolved in 450 ml of deionised water at about 75° C. 2.0 g of a 34.4% titanium sulfate solution are added to this mixture, giving aqueous solution (a).

0.9 g of tert-sodium phosphate 12-hydrate and 107.9 g of sodium carbonate are dissolved in 250 ml of deionised water, giving aqueous solution (b). The two aqueous solutions (a) and (b) are added simultaneously to 200 ml of deionised water with stirring over the course of 15 min. The mixture is stirred for a further 15 min. The resultant solution is evaporated to dryness, and the resultant solid is calcined for 5 h at about 1200° C. Water is added in order to wash out free sulfate. Conventional purification steps with water and drying give the desired phosphors Al_{1.991}O₃:Cr_{0.009}.

### Example 2

### Preparation of the Red Phosphor Na_{0.5}Gd_{0.3}Eu_{0.2}WO₄

2.708 g of gadolinium nitrate hexahydrate and 1.784 g of europium nitrate hexahydrate are dissolved in 100 ml of ethylene glycol [solution 1]. At the same time, a solution of 1.550 g of sodium tungstate dihydrate in 50 ml of deionised water is prepared [solution 2]. 40 ml of solution 1 are initially introduced, a mixture of 45 ml of solution 2, 45 ml of ethylene glycol and 3 ml of NaOH soln. (1M) is added dropwise thereto. After the dropwise addition (the solution has a pH of 7.5), the mixture is heated under reflux for 6 hours.

After the reaction solution has cooled, 200 ml of acetone are added drop-wise, the precipitate is subsequently centrifuged off, washed again with acetone and dried in a stream of air, transferred into a porcelain dish and calcined at 600° C. for 5 h.

### Example 3

### Preparation of the Red Phosphor Na_{0.5}Y_{0.4}Eu_{0.1}MoO₄

3.06 g of yttrium nitrate hexahydrate and 0.892 g europium nitrate hexahydrate are dissolved in 100 ml of ethylene glycol [solution 1]. At the same time, a solution of 1.210 g of sodium molybdate dihydrate in 50 ml of deionised water is prepared [solution 2]. 20 ml of solution 1 are initially introduced, a mixture of 45 ml of solution 2, 45 ml of ethylene glycol and 3 ml of NaOH soln. (1M) are added dropwise to this mixture. After the dropwise addition, the mixture is refluxed for 6 hours.

After the reaction solution has cooled, 200 ml of acetone are added drop-wise, the precipitate is subsequently centrifuged off, washed again with acetone and dried in a stream of air.

The batch is transferred into a muffle furnace, where it is calcined at 600° C. for 5 hours.

### Example 4

### Preparation of the Red Phosphor Na_{0.5}La_{0.3}Eu_{0.2}WO₄ (Precipitation Reaction)

2.120 g of lanthanum chloride hexahydrate and 1.467 g of europium chloride hexahydrate are dissolved in 100 ml of deionised water [solution 1]. At the same time, a solution of 4.948 g of sodium tungstate dihydrate in 100 ml of deionised water is prepared [solution 2]. 100 ml of solution 1 are initially introduced, solution 2 is added dropwise thereto (check pH, should be in the range 7.5-8, if necessary correct using NaOH solution (1M)).

The mixture is subsequently heated under reflux for 6 hours. After the reaction solution has cooled, the precipitate is filtered off with suction and dried, giving a white precipitate.

The batch is calcined at 600° C. for 5 h.

### Example 5

### Preparation of the Red Phosphor Na_{0.5}La_{0.3}Eu_{0.2}MoO₄ by Complexing with Citric Acid

1.024 g of molybdenum(IV) oxide are dissolved in 10 ml of H₂O₂ (30%) with gentle warming. 4.608 g of citric acid, together with 10 ml of dist. H₂O, are added to the yellow solution.

1.040 g of La(NO₃)×6H₂O and 0.714 g of Eu(NO₃)×6H₂O as well as 0.340 g of NaNO₃ are subsequently added, and the mixture is made up to 40 ml.

The yellow solution is dried in a vacuum drying cabinet, with a blue foam initially forming, from which a blue powder finally results. The solid is subsequently calcined at 800° C. for 5 hours.

### Example 6

### Preparation of the Red Phosphor Na_{0.5}La_{0.3}Eu_{0.2}(WO₄)_{0.5} (MoO₄)_{0.5}

2.120 g of lanthanum chloride hexahydrate and 1.467 g of europium chloride hexahydrate are dissolved in 100 ml of deionised water [solution 1]. At the same time, a solution of 1.815 g of sodium molybdate dihydrate and 2.474 g of sodium tungstate dihydrate in 100 ml of deionised water is prepared [solution 2]. 100 ml of solution 1 are initially introduced, solution 2 is added dropwise thereto (pH should be in the range 7.5-8, if necessary correct using NaOH solution (1M)). The mixture is subsequently heated under reflux for 6 hours.

After the reaction solution has cooled, the precipitate is filtered off with suction and dried, and the batch is subsequently calcined at 600° C. for 5 h.

### Example 7

### Preparation of the Red Phosphor La_{1.2}Eu_{0.8}MoO₄ by Complexing with Citric Acid

1.024 g of molybdenum(IV) oxide are dissolved in 10 ml of H₂O₂ (30%) with gentle warming. 4.608 g of citric acid, together with 10 ml of dist. H₂O, are added to the yellow solution.

1.040 g of La(NO₃)×6H₂O and 0.714 g of Eu(NO₃)ₓ₆ H₂O as well as 0.340 g of NaNO₃ are subsequently added, and the mixture is made up to 40 ml.

The yellow solution is dried in a vacuum drying cabinet, with a blue foam initially forming, from which a blue powder finally results. The solid is subsequently calcined at 600° C. for 5 hours.

### Example 8

### Preparation of the Red Phosphor La_{1.2}Eu_{0.8}WO₄ by Complexing with Citric Acid

0.9711 g of tungsten(IV) oxide is dissolved in 10 ml of H₂O₂ (30%) with gentle warming. At the same time, a solution of 0.7797 g of La(NO₃)₃.6; H₂O, 0.5353 g of Eu(NO₃)₃.6H₂O and 1.8419 g of citric acid in 40 ml of H₂O is prepared and added to the blue tungstate soln.

The blue solution is dried in a vacuum drying cabinet, with a blue foam initially forming, from which a blue powder finally results. The solid is subsequently calcined at 600° C. for 5 hours.

### Example 9

### Preparation of the Red Phosphor (Gd_{0.6}Eu_{0.4})₂(WO₄)_{1.5}PO₄

2.23 g of GdCl₃×6 H₂O and 1.465 g of EuCl₃×6 H₂O are dissolved in 100 ml of ethylene glycol (solution 1).

1.73 g of Na₂WO₄ are dissolved in 70 ml of H₂O (solution 2).

0.74 g of K₃PO₄ is dissolved in 70 ml of ethylene glycol (solution 3).

100 ml of solution 1 are initially introduced in a conical flask. Firstly 70 ml of solution 3 are added thereto. The solution becomes cloudy, but becomes clear again after brief stirring. A mixture of 70 ml of solution 2 and 5 ml of NaOH soln. (1M) is subsequently added dropwise. The reaction mixture is transferred into a three-necked flask and heated under reflux with stirring for at least 6 h.

250 ml of acetone are added dropwise to the reaction solution. The precipitate is subsequently centrifuged off and washed again with acetone. The product is then calcined at 650° C. in an oven for 4 hours.

### Example 10

### Preparation of the Green-Emitting Phosphor Ba₂Sio₄:Eu

390 g of barium carbonate, 3.5 g of europium(III) oxide, 63 g of silica gel (SiO₂) and 5.4 g of ammonium chloride are mixed by grinding. The mixture is calcined over a period of 8 h at 1100° C. in a CO atmosphere. After fine grinding, a further 5.4 g of ammonium chloride are added and mixed well to give a homogeneous mixture. This mixture is then again calcined for 14 h at 1200° C. in a CO atmosphere. After grinding, the powder is washed with water in order to remove excess halides and dried in air.

### Example 11

### Preparation of the Green-Emitting Phosphor Lu₃Al₅O₁₂:Ce

537.6 g of ammonium hydrogencarbonate are dissolved in 3 litres of deionised water. 205.216 g of aluminium chloride hexahydrate, 228.293 g of lutetium chloride, hydrated (x H₂O) and 3.617 g of cerium chloride hexahydrate are dissolved in about 400 ml of deionised water and rapidly added dropwise to the hydrogencarbonate solution; during this addition, the pH must be kept at pH 8 by addition of conc. ammonia. The mixture is subsequently stirred for a further hour. After ageing, the precipitate is filtered off and dried in a drying cabinet at about 120° C.

The dried precipitate is ground and subsequently calcined for 4 hours at 1000° C. in air. The product is subsequently re-ground and calcined at 1700° C. in forming gas for 8 hours.

### Example 12

### Production of an LED and Installation in a Liquid-Crystal Display

The phosphor from Example 10 (green phosphor) and the red phosphor from Example 6 are mixed in the mixing ratio 1:2.17 in both components A and B of a silicone resin system OE 6336 from Dow Corning with the aid of a tumble mixer, so that the phosphor concentration in the two components A and B is 10% by weight. 2.2% by weight of silica gel powder from Merck are then added to both mixtures in order to render them thixotropic, and the resultant mixtures are again homogenised in the tumble mixer. 5 ml of component A and 5 ml of component B are in each case mixed to give a homogeneous mixture and introduced into a cartridge which is connected to the metering valve of a dispenser. COB (chip on board) crude LEDs, consisting of bonded InGaN chips having a surface area of 1 mm² each, which emit at a wavelength of 450 nm, are fixed in the dispenser. Domes are applied to each chip by means of the xyz positioning of the dispenser valve. The domes consist of the mixture, rendered thixotropic, of the two silicone components and the two phosphors, and the silica gel powder. The COB-LEDs treated in this way are then subjected to a temperature of 150° C., at which the silicone is solidified. The LEDs can then be put into operation and emit white light having a colour temperature of 6000 K. Several of the LEDs produced above are then installed in a backlighting system of a liquid-crystal display.

### DESCRIPTION OF THE DRAWINGS

The invention will be explained in greater detail below with reference to illustrative embodiments:

FIG. 1 shows a diagrammatic representation of the liquid-crystal display according to the invention (direct-lit design) (1=LCD unit without backlighting; 2=backlighting unit; 3=diffuser; 4=LED with phosphor layer according to the invention; 5=homogeneous luminous flux from the backlighting unit)

FIG. 2 shows a diagrammatic representation of the liquid-crystal display according to the invention (side-lit design) (1=LCD unit without backlighting; 2=backlighting unit; 3=diffuser; 4=LED with phosphor layer according to the invention; 5=homogeneous luminous flux from the backlighting unit)

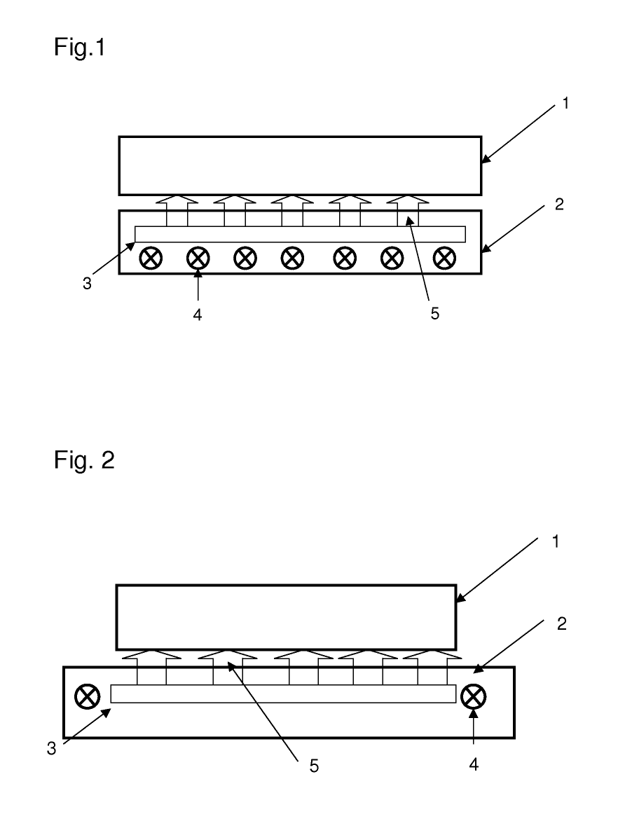

1. Liquid-crystal display fitted with a backlighting system having at least one white light source which comprises at least one semiconductor diode and at least one phosphor layer comprising a combination of at least two phosphors, where at least one phosphor emits red light and at least one phosphor emits green light.

2. Liquid-crystal display according to claim 1, characterised in that the white light source comprises a luminescent indium aluminium gallium nitride semiconductor, in particular of the formula InᵢGaⱼAlₖN, where 0≦i, 0≦j, 0≦k, and l+j+k=1.

3. Liquid-crystal display according to claim 1, characterised in that the white light source comprises a blue-emitting InGaN semiconductor.

4. Liquid-crystal display according claim 1, characterised in that the phosphor layer comprises a red-emitting phosphor as europium(III)- or chromium(III)-activated line emitter.

5. Liquid-crystal display according to claim 4, characterised in that the phosphor layer comprises, as red-emitting phosphor, a europium(III)- or chromium(III)-activated line emitter selected from the group Al₂O₃:Cr, Na_{0.5}Gd_{0.3}Eu_{0.2}WO₄, Na_{0.5}Y_{0.4}Eu_{0.1}MoO₄, Na_{0.5}La_{0.3}Eu_{0.2}WO₄, Na_{0.5}La_{0.3}Eu_{0.2}MoO₄, Na_{0.5}La_{0.3}Eu_{0.2}(WO₄)_{0.5}(MoO₄)_{0.5}, La_{1.2}Eu_{0.8}MoO₄. La_{1.2}Eu_{0.8}WO₄, (Gd_{0.6}Eu_{0.4})₂(WO₄)_{1.5}PO₄.

6. Liquid-crystal display according claim 1, characterised in that the phosphor layer comprises a green-emitting phosphor as cerium(III)- or europium(II)-activated phosphor selected from the group of the thiogallates, silicates, oxonitridosilicates, aluminates, nitrides or garnets.

7. Backlighting system having at least one white light source which comprises at least one semiconductor diode and at least one phosphor layer comprising a combination of at least two phosphors which emit red and green light.

8. Backlighting system according to claim 7, characterised in that the white light source comprises a luminescent indium aluminium gallium nitride semiconductor, in particular of the formula InᵢGaⱼAlₖN, where 0≦i, 0≦j, 0≦k, and l+j+k=1.

9. Backlighting system according to claim 7, characterised in that the white light source comprises a blue-emitting InGaN semiconductor.

10. Backlighting system according to claim 7, characterised in that the phosphor layer comprises a red-emitting phosphor as europium(III)- or chromium(III)-activated line emitter.

11. Backlighting system according to claim 7, characterised in that the phosphor layer comprises a red-emitting phosphor as europium- or chromium-activated line emitter selected from the group Al₂O₃:Cr, Na_{0.5}Gd_{0.3}Eu_{0.2}WO₄, Na_{0.5}Y_{0.4}Eu_{0.1}MoO₄, Na_{0.5}La_{0.3}Eu_{0.2}WO₄, Na_{0.5}La_{0.3}Eu_{0.2}MoO₄, Na_{0.5}La_{0.3}Eu_{0.2}(WO₄)_{0.5}(MoO₄)_{0.5}, La_{1.2}Eu_{0.8}MoO₄, La_{1.2}Eu_{0.8}WO₄, (Gd_{0.6}Eu_{0.4})₂(WO₄)_{1.5}PO₄.

12. Backlighting system according to claim 7, characterised in that the phosphor layer comprises a green-emitting phosphor as cerium(III)- or europium(II)-activated phosphor selected from the group of the thiogallates, silicates, oxonitridosilicates, aluminates, nitrides and garnets.

13. White light source which comprises a blue-emitting indium aluminium gallium nitride semiconductor, in particular of the formula InᵢGaⱼAlₖN, where 0≦i, 0≦j, 0≦k, and l+j+k=1, and a phosphor layer comprising a combination of at least two phosphors which emit red and green light.

14. White light source according to claim 13, characterised in that it comprises a blue-emitting InGaN semiconductor.

15. White light source according to claim 13, characterised in that the phosphor layer comprises a red-emitting phosphor as europium(III)- or chromium(III)-activated line emitter.

16. White light source according to claim 13, characterised in that the phosphor layer comprises a green-emitting phosphor as cerium(III)- or europium(II)-activated phosphor selected from the group of the thiogallates, silicates, oxonitridosilicates, aluminates, nitrides or garnets.

17. Process for the production of a liquid-crystal display fitted with a backlighting system having a white light source, comprising the following steps:
Production of at least one LED which is built up from a blue-emitting InGaAlN semiconductor, in particular of the formula InᵢGaⱼAlₖN, where 0≦i, 0≦j, 0≦k, and l+j+k=1, and a phosphor layer which comprises a combination of a red-emitting phosphor and a green-emitting phosphor.
Installation of one or more LEDs in a housing to give a backlighting system containing diffusers and reflectors.
The backlighting system is combined with a corresponding liquid-crystal unit, containing a front plate with a coloured-filter system, to give the liquid-crystal display.
